(19) United States
(12) Patent Application Publication
(10) Pub. No.: US 2001/0035588 A1
(43) Pub. Date: Nov. 1, 2001

(54) Epoxy resin composition, semiconductor device, and method of judging visibility of laser mark

(76) Inventor: Fumiaki Aga, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/838,161

(22) Filed: Apr. 20, 2001

(30) Foreign Application Priority Data
Oct. 18, 2000 (JP) 2000-317423

(51) Int. Cl. H01L 23/29

(52) U.S. Cl. 257/788; 257/793

(57) ABSTRACT

A principal object is to provide a semiconductor device that uses a semiconductor sealing epoxy resin composition being excellent in visibility of a laser mark and in fluidity characteristics. A semiconductor chip is sealed with a package formed of an epoxy resin. A laser mark is printed on a surface of the package. The color difference between the color of the laser mark and the color of the surface of the package where the laser mark is not formed, as measured by means of a calorimeter, shows a value of 10 or more.

### BACKGROUND OF THE INVENTION

1. Field of the Invention

The present invention generally relates to an epoxy resin composition for sealing semiconductor, and more specifically to a semiconductor sealing epoxy resin composition being excellent in visibility of a laser mark and in fluidity characteristics. The present invention also relates to a semiconductor device that uses such a semiconductor sealing epoxy resin composition. The present invention further relates to a method of judging the visibility of a laser mark.

2. Description of the Background Art

FIG. 8 is a cross-sectional view of a semiconductor device sealed with a conventional epoxy resin composition or the like. A semiconductor chip 2 is disposed on a frame 1. The semiconductor chip 2 is connected to a lead 4 by means of an Au wire 3. The semiconductor chip 2 is sealed mainly with a package 5 formed of an epoxy resin composition or the like. Here, the term “package” may sometimes refer to the whole device including the semiconductor chip; however, in this specification, the term “package” refers to one which is formed of an epoxy resin composition or the like for sealing a semiconductor chip and which does not include the semiconductor chip.

The surface of the package 5 is marked with a product name, a lot number, or the like drawn in a special ink of thermosetting type or UV-curing type. The marking is implemented with a number or the like, as shown in FIG. 9.

However, such a marking and its curing require a lot of time, and also it is not easy to handle with the ink, so that there is an increasing number of manufacturers that adopt a laser mark 6.

However, there has been a problem in that, if the surface of a semiconductor device sealed with a conventional semiconductor sealing epoxy resin composition is marked with a laser mark, the contrast between the marked part 6 and the non-marked part 7 is indistinct, making it difficult to read the printed marks.

Further, although there has been some reports on improvement in the visibility of a laser mark, they are not shown in quantitative values, and it is not clear whether they are good or poor.

### SUMMARY OF THE INVENTION

The present invention has been made in order to solve the aforementioned problems of the prior art, and an object thereof is to provide a semiconductor sealing epoxy resin composition being excellent in visibility of a laser mark.

Another object of the present invention is to provide a semiconductor sealing epoxy resin composition being excellent in visibility of a laser mark and in fluidity characteristics.

Still another object of the present invention is to provide a semiconductor device having a package formed of such a semiconductor sealing epoxy resin composition.

Still another object of the present invention is to provide a method of judging the visibility of a laser mark printed on the surface of a package in a semiconductor device sealed with the package formed of an epoxy resin composition.

A semiconductor sealing epoxy resin composition according to a first aspect of the present invention is directed to an epoxy resin composition that seals a semiconductor chip. The color difference between the color of the epoxy resin and the color of a standard substance stored in a colorimeter shows a value of 30 or more.

A semiconductor sealing epoxy resin composition according to a second aspect of the present invention is directed to an epoxy resin composition that seals a semiconductor chip. The epoxy resin composition contains an epoxy resin and a filler that fills the inside of the epoxy resin. The aforesaid filler contains from 10 to 15 wt % of a filler component having an average particle size of 10 μm or less with respect to total filler components.

A semiconductor device according to a third aspect of the present invention includes a semiconductor chip, a package formed of an epoxy resin that seals the semiconductor chip, and a laser mark printed on a surface of the package. The color difference between the color of the laser mark and the color of the surface of the package where the laser mark is not formed, as measured by means of a calorimeter, shows a value of 10 or more.

In a semiconductor device according to a fourth aspect of the present invention, the package is colored with a dye.

A semiconductor device according to a fifth aspect of the present invention includes a semiconductor chip, a package formed of an epoxy resin that seals the semiconductor chip, and a laser mark printed on a surface of the package. The color difference between the color of the epoxy resin and the color of a standard substance stored in a calorimeter shows a value of 30 or more.

A semiconductor device according to a sixth aspect of the present invention includes a semiconductor chip, a package formed of an epoxy resin that seals the semiconductor chip, and a filler that fills the inside of the epoxy resin. The aforesaid filler contains from 10 to 15 wt % of a filler component having an average particle size of 10 μm or less with respect to total filler components.

A method of judging the visibility of a laser mark according to a seventh aspect of the present invention is directed to a method of judging the visibility of a laser mark printed on a surface of a package in a semiconductor device sealed with the package formed of an epoxy resin. First, the color difference value between the color of the laser mark and the color of the surface of the package where the laser mark is not formed, is measured by means of a calorimeter. Then, whether the color difference value shows a value of 10 or more is judged.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device in the first step in the order of a method for forming a laser mark;

FIG. 2 is a cross-sectional view of a semiconductor device in the second step in the order of a method for forming a laser mark;

FIG. 3 is a cross-sectional view of a semiconductor device in the third step in the order of a method for forming a laser mark;

FIG. 4 is an SEM photograph (1,000-fold enlarged view) of a sample with good visibility of a laser mark;

FIG. 5 is an SEM photograph (2,000-fold enlarged view) of a sample with good visibility of a laser mark;

FIG. 6 is an SEM photograph (1,000-fold enlarged view) of a sample with poor visibility of a laser mark;

FIG. 7 is an SEM photograph (2,000-fold enlarged view) of a sample with poor visibility of a laser mark;

FIG. 8 is a cross-sectional view of a semiconductor device sealed with a semiconductor sealing resin; and

FIG. 9 is a conceptual view of a laser mark.

### DESCRIPTION OF THE PREFERRED EMBODIMENTS

Hereafter, preferred embodiments of the present invention will be described with reference to the attached drawings.

First Embodiment

Hitherto, with respect to the visibility of a laser mark, whether it is good or poor has been judged by a human eye. Therefore, the visibility of a laser mark has varied to a great extent depending on the state of the sample and the reflectivity of light.

This embodiment is directed to a method of quantitatively determining the color difference of a laser mark from the color of a matrix (mold resin) by means of a colorimeter. The colorimeter which was put to use was a calorimeter CR-241 manufactured by Minolta Co., Ltd. Here, the colorimeter determines the color difference (hereafter referred to as color value) between the color of the black part (matrix) of the mold resin and the color of a standard substance stored in the calorimeter.

First, in a semiconductor device having a laser mark formed thereon, the color value of the black part (matrix) of the mold resin was measured by means of the calorimeter. Next, the color value of the part marked with a laser mark was likewise measured by means of the calorimeter. The contrast difference of the laser mark relative to the matrix (mold resin) can 5 be represented by the difference in color value (color difference value) between the black part (matrix) of the mold resin and the part marked with the laser mark thus determined. The results are shown in Table 1.

TABLE 1

| Type | | Sample A | Sample B |
|---|---|---|---|
| Main agent | | cresol novolak type epoxy | same as left |
| | | resin (80) | |
| | | biphenyl type epoxy resin | same as left |
| | | (20) | |
| Curing agent | | phenol novolak resin (50) | phenol novolak resin (100) |
| | | naphthalene type | naphthalene type phenolic |
| | | phenolic resin (50) | resin (0) |
| Catalyst | | triphenylphosphine | same as left |
| Filler | Gram shape | spherical | same as left |
| | Amount | 84 wt % | same as left |
| Conventional judgement | | hardly visible | visible |
| Present | Color difference value | 10 | 16 |
| case | Judgement | hardly readable | readable |

In Table 1, the samples A and B each contain 3 wt % of carbon black.

Further, fused silica (SiO₂) was used as a filler. The sample A contains a phenol novolak resin (50 parts) and a naphthalene type phenolic resin (50 parts) as a curing agent, whereas the sample B contains only a phenol novolak resin (100 parts). The color difference value of the sample A was 10, whereas the color difference value of the sample B was 16. The sample A was judged as being difficult to read by a human naked eye. The sample B was judged as being readable by a human naked eye.

As a result of tests under various conditions, it could be concluded that those in which the contrast difference (i.e. the color difference value) of the laser mark relative to the matrix (mold resin) is 10 or more, are readable by a human naked eye. In other words, this color difference value was found to be a great factor for the visibility of a laser mark.

Here, the aforesaid sample B in which the color difference value was 16 was one in which the amount of use of naphthalene type phenolic resin having a black color was zero.

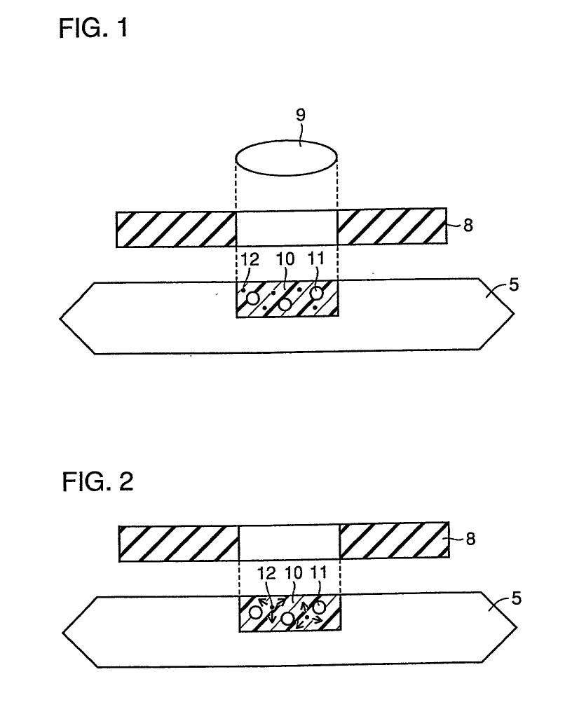

FIGS. 1 to 3 are views showing steps in a method for forming a laser mark. A laser light is radiated from a laser radiator 9 via a printing mask 8 onto a package 5 that seals a semiconductor chip. The package 5 contains a resin 10, a filler 11, and carbon black 12.

Referring to FIGS. 1 and 2, the carbon black 12 absorbs laser energy in a part radiated by the laser. This allows heat to be transmitted to the carbon black 12 and the epoxy resin 10, and these are thermally decomposed and evaporated to leave a residue as a mark to be read.

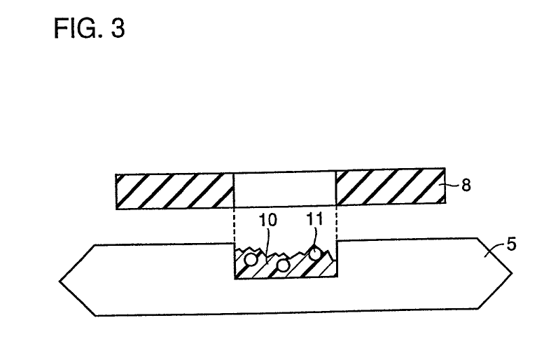

In other words, referring to FIG. 3, the carbon black has disappeared in the part radiated with laser, leaving only the epoxy resin 10 and the filler 11. Needless to say, the carbon black, the filler, and the resin all remain in the parts of the package 5 other than the part radiated with laser. The part radiated with laser has a weaker blackness than other parts of the package due to absence of the carbon black. Therefore, the part radiated with laser can be read as a mark.

Repeatedly described, in the sample A, the color difference between the color of the laser mark (the part radiated with laser) and the color of the surface of the package where the laser mark is not formed, as measured by means of a calorimeter, is 10. In the sample B, the color difference between the color of the laser mark and the color of the surface of the package where the laser mark is not formed, as measured by means of a colorimeter, is 16. As a result of trial and error, it has been found out that those judged to be readable by a human naked eye are ones in which the color difference value of the laser mark is 10 or more.

Second Embodiment

As described above, the carbon black contained in the mold resin absorbs laser energy, whereby heat is transmitted to the carbon black and the epoxy resin, and these are thermally decomposed and evaporated to leave a residue as a mark to be read. The visibility of the laser mark is judged by the color difference between the color of the mark and the color of the part where the laser mark is not formed.

In the first embodiment, the sample A and the sample B were made differently by changing the resin. In the second embodiment, studies were made by focusing on the resin. Here, an attempt was made to determine the color difference value, as measured by a colorimeter, of samples that do not contain carbon black. The result is shown in Table 2.

TABLE 2

| Type | | Sample A | Sample B |
|---|---|---|---|
| Main agent | | cresol novolak type epoxy | same as left |
| | | resin (80) | |
| | | biphenyl type epoxy resin | same as left |
| | | (20) | |
| Curing agent | | phenol novolak resin (50) | phenol novolak resin (100) |
| | | naphthalene type phenolic | naphthalene type phenolic |
| | | resin (50) | resin (0) |
| Catalyst | | triphenylphosphine | same as left |
| Filler | Grain shape | spherical | same as left |
| | Amount | 84 wt % | same as left |

| | | |
|---|---|---|
| Color difference value | 29.47 | 54.05 |
| without carbon black | | |
| Color difference value of | 10 | 16 |
| laser mark | | |

In Table 2, fused silica (SiO₂) was used as a filler.

The sample A shows that the color difference between the color of the epoxy resin (containing no carbon black) and the color of a standard substance (black substance) stored in the colorimeter is 29.47. The sample B shows that the color difference between the color of the epoxy resin (containing no carbon black) and the color of the standard substance (black substance) stored in the colorimeter is 54.05. When carbon black was added to these samples A and B, the color difference values of the laser mark were 10 and 16, respectively. The color difference value of the laser mark was determined in the same manner as in the first embodiment.

Referring to Table 2, the one in which the color difference between the color of the epoxy resin containing no carbon black (sample B) and the color of the standard substance stored in the colorimeter showed a value of 54.05, had a laser mark color difference value of 16 and can be judged as being readable.

As a general summary of the various studies carried out, it is concluded that those in which the color difference between the color of the epoxy resin (containing no carbon black) and the color of the standard substance stored in the colorimeter shows a value of 30 or more, give a laser mark with a color difference value of 10 or more.

Third Embodiment

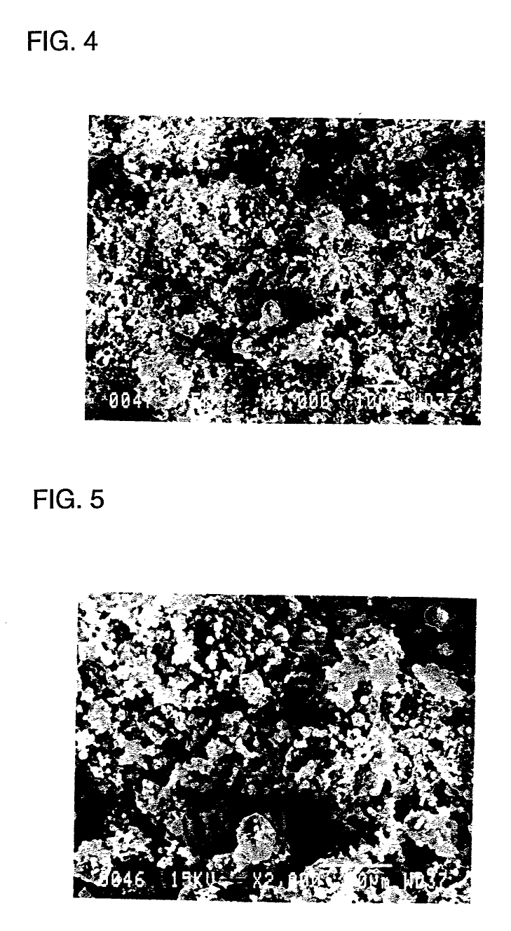

A laser mark is formed by thermal decomposition and evaporation of mold resin and carbon black by laser energy. It has been found out that the visibility of a laser mark is influenced by the state of the filler after thermal decomposition and evaporation of these. Laser-radiated surfaces of a sample with good visibility of a laser mark and a sample with poor visibility were observed by a scanning type electron microscope (SEM). FIGS. 4 and 5 are SEM photographs of a portion of a letter part of a laser mark in a sample with good visibility of the laser mark, where FIG. 4 is a 1,000-fold enlarged image, and FIG. 5 is a 2,000-fold enlarged image.

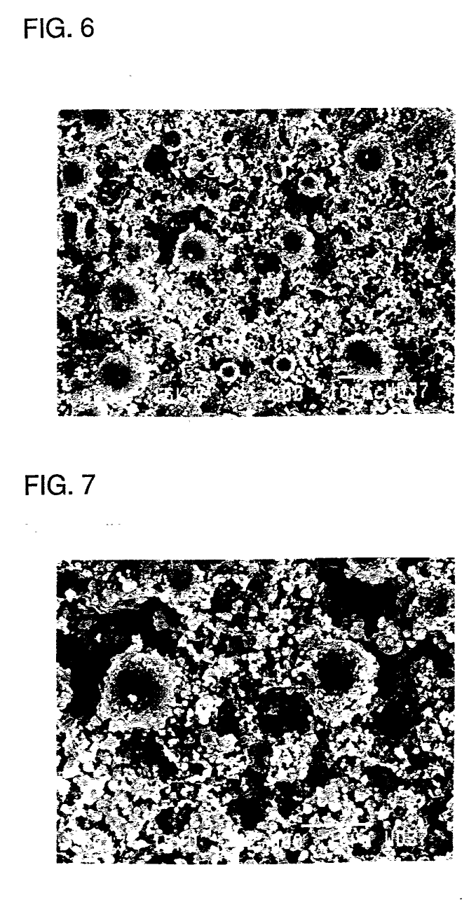

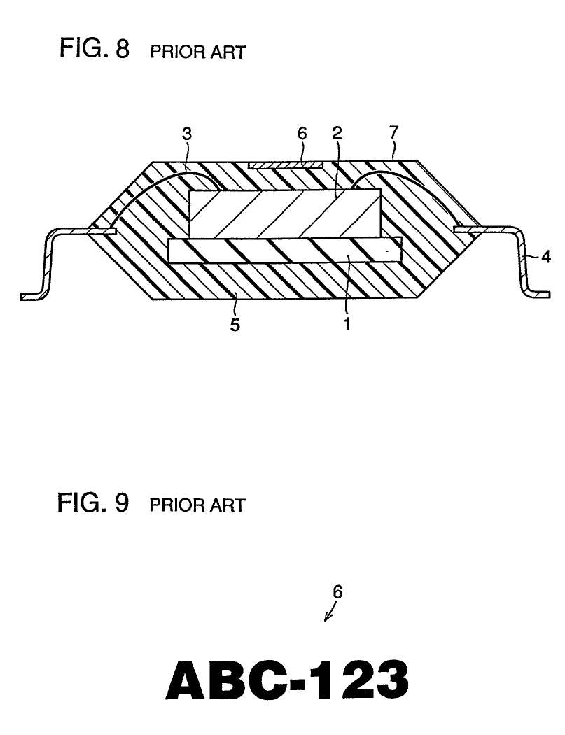

FIGS. 6 and 7 are SEM photographs of a portion of a letter part of a laser mark in a sample with poor visibility of the laser mark, where FIG. 6 is a 1,000-fold enlarged image, and FIG. 7 is a 2,000-fold enlarged image.

These Figures depict an image of a filler. It has been found out that the sample with good visibility has a small filler, whereas the sample with poor visibility has a large filler. Further, it has been found out that, in the sample with good visibility, a fine filler of 10 μm or less is present in a large number. This shows that the presence of a fine filler improves the visibility of a laser mark by random reflection of light. In other words, the visibility is improved if light hits the filler to be randomly reflected.

However, if a prismatic filler or a filler having a size of 10 μm or less is contained in an amount of 15 wt % or more in order to increase the random reflection of light, the fluidity characteristics of the mold resin decrease to adversely affect the moldability of the semiconductor device (package).

Therefore, it has been found out that, in order to obtain both the visibility of a laser mark and the moldability of a package, it is important to select the particle size and the amount of the filler to be added.

In order to make a further detailed study on these, the particle size of the filler was changed, namely, various samples containing a filler having an average particle size of 10 μm or less were prepared to confirm the visibility of the laser mark and the fluidity characteristics. The results are shown in Table 3.

TABLE 3

| Type | | Sample C | Sample D | Sample E | Sample F |
|---|---|---|---|---|---|
| Main agent | | cresol novolak type | same as left | same as left | same as left |
| | | epoxy resin (80) | | | |
| | | biphenyl type | same as left | same as left | same as left |
| | | epoxy resin (20) | | | |
| Curing agent | | phenol novolak | same as left | same as left | same as left |
| | | resin (50) | | | |
| | | naphthalene type | same as left | same as left | same as left |
| | | phenolic resin (50) | | | |
| Catalyst | | triphenylphosphine | same as left | same as left | same as left |
| Filler | Grain shape | spherical | same as left | same as left | same as left |
| | Amount | 84 wt % | same as left | same as left | same as left |
| | Amount of | 5 wt % | 10 wt % | 15 wt % | 20 wt % |
| | 10 μm or less | | | | |
| Fluidity | Spiral flow | 170 cm(◯) | 160 cm(◯) | 155 cm(◯) | 140 cm(X) |
| | Gel time | 38 sec(◯) | 38 sec(◯) | 38 sec(◯) | 38 sec(◯) |
| | Viscosity | 70 poise(◯) | 70 poise(◯) | 80 poise(◯) | 120 poise(◯) |

| | | | | |
|---|---|---|---|---|
| Laser mark color | 10.5(Δ) | 13.2(◯) | 14.3(◯) | 16.7(◯) |
| difference value | | | | |

In Table 3, the samples C, D, E, and F each contain 3 wt % of carbon black. Further, fused silica (SiO₂) was used as a filler.

The contained amount of the filler having a size of 10 μm or less was increased successively in the order of samples C, D, E, and F. When the amount of the filler having a size of 10 μm or less was increased, the color difference value of the laser mark increased. In other words, the visibility of the laser mark improved.

On the other hand, it was found out that, when the amount of the filler having a particle size of 10 μm or less increased, the spiral flow and the viscosity decreased, whereby the fluidity characteristics of the mold resin decreased and, as a result, the moldability of the package was adversely affected. In Table 3, the mark ∘ represents large usability, the mark Δ represents some usability, and the mark × represents little usability.

From these results, it has been judged that the filler preferably contains from 10 to 15 wt % of a filler component having an average particle size of 10 μm or less with respect to the total filler components. If the filler having an average particle size of 10 μm or less is contained within this range, the visibility of the laser mark was compatible with the moldability.

Here, when the package was colored with a dye, the color of the resin could be prevented from changing.

As described above, according to the present invention, the visibility of a laser mark can be judged by a quantitative value. In other words, whether the contrast is good or poor can be judged by a quantitative value. Further, the present invention makes it possible to obtain a semiconductor sealing epoxy resin composition having both a good visibility of a laser mark and good fluidity characteristics of a mold resin. As a result, when the present invention is applied to a sealing package of an electric or electronic component, a clear printing by a YAG laser marking can be obtained at a high speed and at a low voltage, thereby producing an effect of contributing to the reduction in the steps and costs to a great extent.

While the invention has been shown and described in detail, the foregoing description is in all aspects illustrative and not restrictive. It is therefore understood that numerous other modifications and variations can be devised without departing from the scope of the invention.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An epoxy resin composition that seals a semiconductor chip, wherein a color difference between a color of said epoxy resin and a color of a standard substance stored in a calorimeter shows a value of 30 or more.

2. An epoxy resin composition that seals a semiconductor chip, said epoxy resin composition including an epoxy resin and a filler that fills an inside of said epoxy resin, wherein said filler contains from 10 to 15 wt % of a filler component having an average particle size of 10 μm or less with respect to total filler components.

3. A semiconductor device including:
a semiconductor chip;
a package formed of an epoxy resin that seals said semiconductor chip; and
a laser mark printed on a surface of said package, wherein a color difference between a color of said laser mark and a color of the surface of said package where the laser mark is not formed, as measured by means of a calorimeter, shows a value of 10 or more.

4. The semiconductor device according to claim 3, wherein said package is colored with a dye.

5. A semiconductor device including:
a semiconductor chip;
a package formed of an epoxy resin that seals said semiconductor chip; and
a laser mark printed on a surface of said package, wherein a color difference between a color of said epoxy resin and a color of a standard substance stored in a colorimeter shows a value of 30 or more.

6. A semiconductor device including:
a semiconductor chip;
a package formed of an epoxy resin that seals said semiconductor chip; and
a filler that fills an inside of said epoxy resin, wherein said filler contains from 10 to 15 wt % of a filler component having an average particle size of 10 μm or less with respect to total filler components.

7. A method of judging a visibility of a laser mark printed on a surface of a package in a semiconductor device sealed with the package formed of an epoxy resin, said method including the steps of:
measuring a color difference value between a color of said laser mark and a color of the surface of said package where the laser mark is not formed, by means of a colorimeter; and
judging whether said color difference value shows a value of 10 or more.
